(19) United States
(12) Patent Application Publication
(10) Pub. No.: US 2023/0387309 A1
(43) Pub. Date: Nov. 30, 2023

(54) TRANSISTOR STRUCTURE

(71) Applicant: Invention And Collaboration Laboratory Pte. Ltd., Singapore (SG)

(72) Inventor: Chao-Chun Lu, Taipei City (TW)

(73) Assignee: Invention And Collaboration Laboratory Pte. Ltd., Singapore (SG)

(21) Appl. No.: 18/200,588

(22) Filed: May 23, 2023

Related U.S. Application Data
(60) Provisional application No. 63/345,446, filed on May 25, 2022.
(60) Provisional application No. 63/409,247, filed on Sep. 23, 2022.

(51) Int. Cl. H01L 29/78; H01L 29/08; H01L 29/10; H01L 29/423

(52) U.S. Cl. CPC H01L 29/7851; H01L 29/7827; H01L 29/7809; H01L 29/0869; H01L 29/0886; H01L 29/1083; H01L 29/4236

(57) ABSTRACT

A transistor structure includes a substrate, a source region, a drain region, a trench, and a central pole. The substrate has a convex structure, wherein the convex structure has a conductive channel region. The source region contacts with a first end of the conductive channel region. The drain region contacts with a second end of the conductive channel region. The trench is formed in the convex structure and between the first end and the second end. The central pole is formed in the trench, wherein a material of the central pole is different from that of the conductive channel region.

### CROSS REFERENCE TO RELATED APPLICATIONS

This application claims the benefit of U.S. Provisional Application No. 63/345,446, filed on May 25, 2022. Further, this application claims the benefit of U.S. Provisional Application No. 63/409,247, filed on Sep. 23, 2022. The contents of these applications are incorporated herein by reference.

### BACKGROUND OF THE INVENTION

### 1. Field of the Invention

The present invention relates to a transistor structure, and particularly to a transistor structure which can effectively reduce the leakage current path during the OFF state of the transistor structure, form a solid wall to clamp an active region or a narrow convex structure of the transistor, and make most the source/drain areas isolated by insulation materials.

### 2. Description of the Prior Art

Monolithic integration of silicon devices for integrated circuits (IC) has achieved realization of more than 50 billion of transistors on a die in the year of 2021, which has been named as an era of GSI (Gigabyte-Scale Integration, i.e. Achieving more than billions of transistors on a die) from VLSI (Very Large Scale Integration having more than millions of transistors on a die).

Such accomplishments of making much higher integration capacity of transistors on a die have sharply enabled more powerful microsystems with significantly improved PPAC (higher Performance, better Power managing capability, effective usage of Area and lower Cost per bit), thus creating many powerful chips such as central processing unit (CPU), graphics processing unit (GPU), field programmable gate array (FPGA), system on a chip (SOC), static random-access memory (SRAM), dynamic random access memory (DRAM), etc., which enhances system capabilities so as to continually support Moore's Law which formed a base to create an exponential economic growth. With such a high productivity generated from GSI to grow new applications which stimulates fast growth of economic scale, there are very strong demands to integrate more transistors on a die. So it is expected that semiconductor industry tries every best efforts to march toward a TSI (Tera-Scale Integration), that is, integration of more than trillions of transistors on a die for a chip. Therefore, how to sharply improve the transistor to meet this TSI challenge requires inventions and engineering improvements of some fundamentally changed transistor structure with better PPAC. For example, if a chip does integrate one trillion transistors on a die, if each transistor is set at achieving a standby current (or called IOFF) about 0.5 pA (abbreviation of Ampere), then a total of one trillion of transistors will have its IOFF of a die is approaching 0.5 Amperes.

The state-of-art transistor with less than 20 nm technologies can hardly achieved this IOFF of 0.5 pA, however; even by using various transistor structures such as FinFET or Tri-Gate designs, some IOFF's can be as large as 5 to 10 pA. How to continuously shrink the device dimensions plus to reduce IOFF is the key challenge.

An example of state-of-the-art Field-Effect transistor (FinFET) with active region which is formed as a fin structure is shown in FIG. 1. A gate structure 5 of the transistor using some conductive material (like metal, polysilicon or polyside, etc.) over an insulator or dielectric layer (such as oxide, oxide/nitride or some high-k dielectric, etc.) is formed on a fin structure or a three-dimensional convex silicon surface. Using an NMOS (n-type metal-oxide-semiconductor) transistor as example, there are source region 11 and drain region 12 which are formed by an ion-implantation plus thermal annealing technique to implant high concentration n-type dopants into a p-type substrate (or a p-well) which thus results in two separated n+/p junction areas. Furthermore, to lessen impact ionization and hot carrier injection prior to highly doped n+/p junction, it is common to form a lightly doped drain (LDD) region 13 before the highly doped n+ source/drain region by ion-implantation plus thermal annealing technique, and such ion-implantation plus thermal annealing technique frequently causes the LDD regions 13 penetrating underneath the gate structure, as shown in FIG. 1. Therefore, a length of an effective channel 14 between the LDD regions 13 is unavoidably shortened.

On the other hand, the advancement of manufacturing process technologies is continuing to move forward rapidly by scaling down the geometries of devices in both horizontal and vertical dimensions (such as the minimum feature size called as Lamda (A) is shrunk from 28 nm down to 5 nm or 3 nm). But many problems are introduced or getting worse due to such FinFET or Tri-gate geometry scaling:
(1) As a gate length of the transistor is scaled down, it's OFF state current (IOFF) is getting harder to be reduced. A higher leakage current path (a dash rectangle region 16 in FIG. 2 which is a cross section) is formed within fin structure, rather than only along a surface of the fin structure. Such leakage current path was evaluated and simulated as shown in FIG. 3. FIG. 3(a) is a 3D FinFET structure under Technology Computer-Aided Design (TCAD) simulation, FIG. 3(b) is a cross section view of the 3D FinFET structure corresponding to a red dot rectangle 18 in FIG. 3(a), and FIG. 3(c) is an OFF state current distribution (see, “Impact of Current Flow Shape in Tapered (Versus Rectangular) FinFET on Threshold Voltage Variation Induced by Work-Function Variation”, IEEE TRANSACTIONS ON ELECTRON DEVICES, VOL. 61, NO. 6, JUNE 2014).
(2) As shown in FIG. 1, because dimensions of the NMOS transistor are scaled down, it's getting harder to align LDD junction edge (or source/drain edge) to the edge of the gate structure 5 in a perfect position by only following the conventional self-alignment method of using gate, spacer and ion-implantation formation. In addition, the thermal annealing process for removing the ion-implantation damages must count on high temperature processing techniques such as rapid thermal annealing method by using various energy sources or other thermal processes. One problem thus created is that a gate-induced drain leakage (GIDL) current and the GIDL issued is hard to be controlled regardless the fact that it should be minimized in order to reduce leakage currents; the other problem as created is that a length of the effective channel 14 is difficult to be controlled and so the short channel effect (SCE) is hardly minimized. Additionally, it is also difficult to adjust the relative position between the source/drain edges to the edge of the gate structure 5 such that the GIDL could be better controlled.
(3) Since the ion-implantation to form the LDDs 13 (or the n+/p junction in NMOS or the p+/n junction in PMOS (p-type metal-oxide-semiconductor)) works like bombardments in order to insert ions from a top of a silicon surface straight down to the substrate, it is hard to create uniform material interfaces with lower defects from the source 11 and the drain 12 to the effective channel 14 and the substrate-body regions since the dopant concentrations are non-uniformly distributed vertically from the top surface with higher doping concentrations down to the junction regions with lower doping concentrations.
(4) Furthermore, when the horizontal dimension of the NMOS transistor is scaled down to 7 nm, 5 nm or 3 nm, the height of the fin structure (such as 50˜100 nm) of the NMOS transistor is far larger than a width of the fin structure (such as 3˜10 nm) of the NMOS transistor such that the fin structure is vulnerable or even collapsed during the subsequent processes (such as source/drain formation, gate formation, etc.).

Therefore, the present invention discloses a new 3D transistor structure to solve the above-mentioned disadvantages of the conventional transistor, for example, the new 3D transistor structure can reduce IOFF by 10 to 100 times.

### SUMMARY OF THE INVENTION

An embodiment of the present invention provides a transistor structure. The transistor structure includes a substrate, a source region, a drain region, a trench, and a central pole. The substrate has a convex structure, wherein the convex structure has a conductive channel region. The source region contacts with a first end of the conductive channel region. The drain region contacts with a second end of the conductive channel region. The trench is formed in the convex structure and between the first end and the second end. The central pole is formed in the trench, wherein a material of the central pole is different from that of the conductive channel region.

According to one aspect of the present invention, the substrate is made of silicon, and the central pole is encompassed by a surrounding ring of silicon within the convex structure.

According to one aspect of the present invention, the material of the central pole is a non-conductive material.

According to one aspect of the present invention, the non-conductive material is oxide thermally grown in the trench.

According to one aspect of the present invention, the transistor structure further includes a gate region and an isolation wall. The gate region crosses over the conductive channel region and the non-conductive material. The isolation wall clamps sidewalls of the convex structure.

According to one aspect of the present invention, the transistor structure further includes a STI layer which surrounds the isolation wall.

According to one aspect of the present invention, the transistor structure further includes a spacer layer which is formed on a sidewall of the gate region.

According to one aspect of the present invention, the transistor structure further includes a first concave and a second concave. The first concave is in the convex structure and accommodates the source region, wherein an edge of the first concave is aligned or substantially aligned with an edge of the gate region. The second concave is in the convex structure and accommodates the drain region, wherein an edge of the second concave is aligned or substantially aligned with another edge of the gate region. The source region and the drain region are independent from the substrate.

According to one aspect of the present invention, the transistor structure further includes an LDD region, a heavily doped region, and a metal region. The LDD region laterally extends from the first end of the conductive channel region. The heavily doped region laterally extends from the LDD region. The metal region contacts the heavily doped region.

According to one aspect of the present invention, the transistor structure further includes an L-shape oxide layer and a nitride layer. The oxide layer is positioned in the first concave, wherein the oxide layer includes a vertical portion facing the conductive channel region and a lateral portion covering a bottom of the first concave.

Another embodiment of the present invention provides a transistor structure. The transistor structure includes a substrate. The substrate has a convex structure, wherein the convex structure has a conductive channel region which includes a first vertical conductive sheet and a second vertical conductive sheet. The first vertical conductive sheet is separate from the second vertical conductive sheet by a central pole positioned in the conductive channel region.

According to one aspect of the present invention, a width of the first vertical conductive sheet or the second vertical conductive sheet is between 1˜5 nm.

According to one aspect of the present invention, a height of the non-conductive sheet is between 30˜60 nm.

According to one aspect of the present invention, a length of the central pole is shorter than that of the first vertical conductive sheet or the second vertical conductive sheet.

According to one aspect of the present invention, the transistor structure further includes a source region, a drain region, and a gate region. The source region contacts with a first end of the conductive channel region, and electrically connects to the first vertical conductive sheet and the second vertical conductive sheet. The drain region contacts with a second end of the conductive channel region, and electrically connects to the first vertical conductive sheet and the second vertical conductive sheet. The gate region crosses over the conductive channel region and the central pole. Wherein a bottom of a gate conductive material of the gate region outside the convex structure is lower than the bottom surface of the source region or the drain region

According to one aspect of the present invention, the transistor structure further includes a selective grown semiconductor layer which covers the first vertical conductive sheet and the second vertical conductive sheet.

Another embodiment of the present invention provides a transistor structure. The transistor structure includes a substrate, a first conductive region, and a second conductive region. The substrate has a convex structure, wherein the convex structure has a conductive channel region. The first conductive region contacts with a first end of the conductive channel region. The second conductive region contacts with a second end of the conductive channel region. A conductive current during an ON state of the transistor structure is diverged in the conductive channel region extending from the second conductive region to the first conductive region.

According to one aspect of the present invention, the conductive current is diverged into multiple paths in the conductive channel region.

According to one aspect of the present invention, a leakage current during an OFF state of the transistor structure is lower than 1 pA.

Another embodiment of the present invention provides a transistor structure. The transistor structure includes a substrate, a trench, and a gate region. The substrate has a convex structure, wherein the convex structure includes a conductive channel region made of a semiconductor material. The trench is formed in the convex structure, wherein the trench is encompassed by a ring shape of the semiconductor material. The gate region crosses over the conductive channel region and the trench.

According to one aspect of the present invention, the conductive channel region comprises the ring shape of the semiconductor material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram illustrating a FinFET according to the prior art.

FIG. 2 is a diagram illustrating a higher leakage current path formed within fin structure.

FIG. 3 is a diagram illustrating a 3D FinFET structure under Technology Computer-Aided Design (TCAD) simulation, a cross section view of the 3D FinFET structure, and an OFF state current distribution.

FIG. 4A is a flowchart illustrating a manufacturing method of a fin field-effect transistor (FinFET) according to one embodiment of the present invention.

FIG. 4B, FIG. 4C, FIG. 4D, FIG. 4E are diagrams illustrating FIG. 4A.

FIG. 5 is a diagram illustrating the pad-oxide layer being grown, the pad-nitride layer being deposited, and the trench being formed.

FIG. 6 is a diagram illustrating the oxide spacer being deposited on the p-type well and the nitride spacer being deposited on the oxide spacer.

FIG. 7 is a diagram illustrating the shallow trench isolation (STI) being formed and the thin nitride layer being deposited.

FIG. 8 is a diagram illustrating the gate region across the active region and the isolation region being defined.

FIG. 9 is a diagram illustrating the photolithographic (PR) mask being removed.

FIG. 10 is a diagram illustrating the nitride spacer-2 being formed and based on the nitride spacer-2 to form the trench.

FIG. 11 is a diagram illustrating the thermal oxide being grown to fill the trench to form the central pole and then the nitride cap over the central pole being formed.

FIG. 12 is a diagram illustrating the exposed STI being etched back to create the fin-shape.

FIG. 13 is a diagram illustrating the nitride cap and the nitride spacer-2 in the central pole related area being removed.

FIG. 14 is a diagram illustrating the pad-oxide layer in the central pole related area and the oxide spacer covering the fin-shape being removed, and the STI corresponding to the gate region being also etched down.

FIG. 15 is a diagram illustrating the gate dielectric being formed and the gate material being deposited in the gate region.

FIG. 16 is a diagram illustrating the composite cap layer being deposited and then the STI being etched.

FIG. 17 is a diagram illustrating the pad-nitride layer and the pad-oxide layer being etched away, some portion of the STI being etched back, and the oxide-2 spacer and the nitride-2 spacer being formed on the edges of the gate material.

FIG. 18 is a diagram illustrating some exposed silicon areas being etched away to create shallow trenches for the source and the drain, using the thermal oxidation process to grow the oxide-3 layer, and using CVD to deposit nitride.

FIG. 19 is a diagram illustrating the tungsten layer being deposited and then the TiN layer being deposited above the tungsten layer.

FIG. 20 is a diagram illustrating the portion of the oxide-3V layer being etched away to reveal silicon sidewalls, then the n-type LDDs, the n+ doped source, and n+ doped drain being formed, and then the TiN layer the Tungsten layer being deposited.

FIG. 21 is a diagram illustrating the selective growth Si layer being formed to increase the fin width of the fin structure according to another embodiment of the present invention.

FIG. 22 is a diagram illustrating the structure of the another proposed FinFET according to another embodiment of the present invention.

FIG. 23, FIG. 24 are diagrams illustrating the TCAD simulation results for the conventional fin structure of the FinFET.

FIG. 25, FIG. 26 are diagrams illustrating the TCAD simulation results according to the present invention with central pole in fin structure.

FIG. 27A is a diagram illustrating the trench corresponding to the central pole related area with a depth around 75 nm.

FIG. 27B is a diagram illustrating the central pole with a depth around 75 nm.

FIG. 28 is a diagram illustrating a corresponding 3DCFET which has the central pole 1302 with the depth around 75 nm.

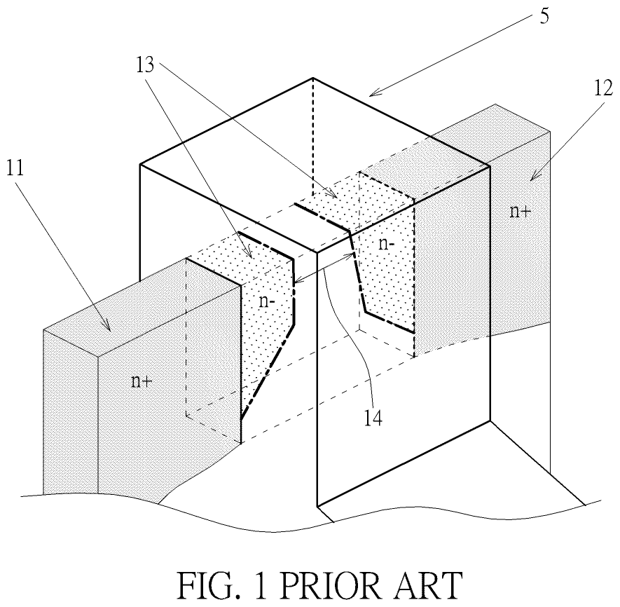

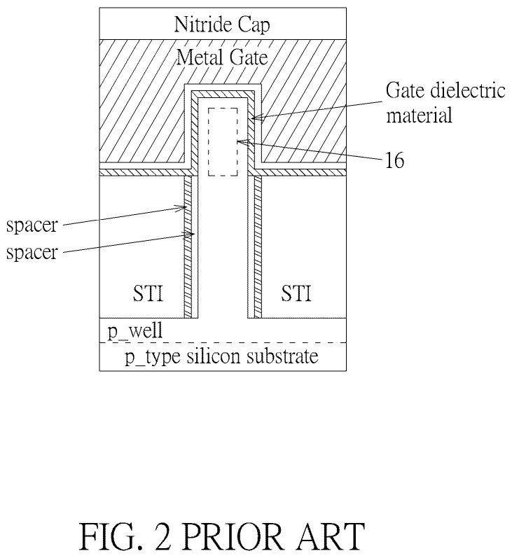

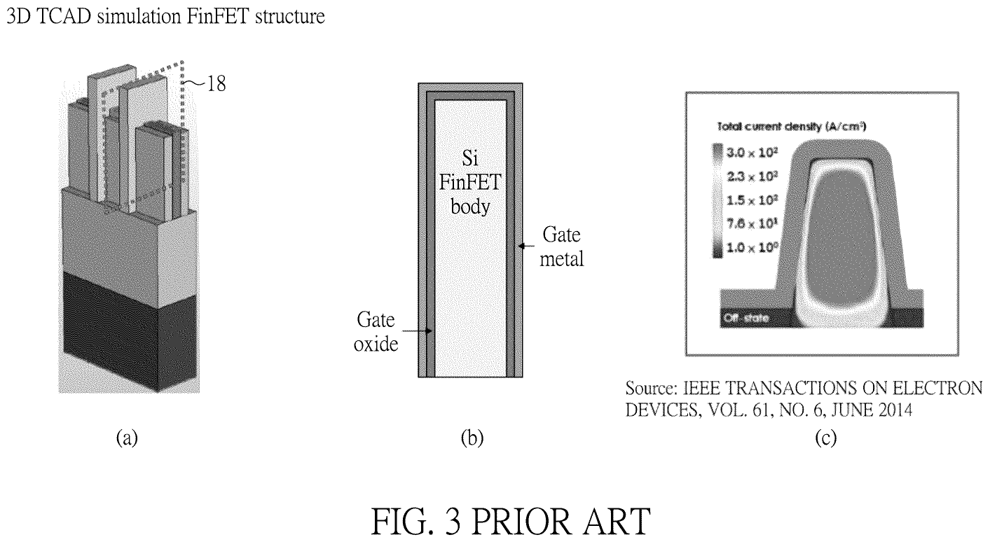

### DETAILED DESCRIPTION

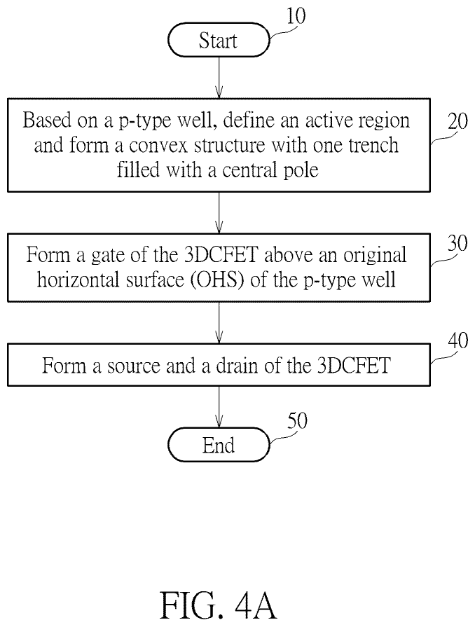

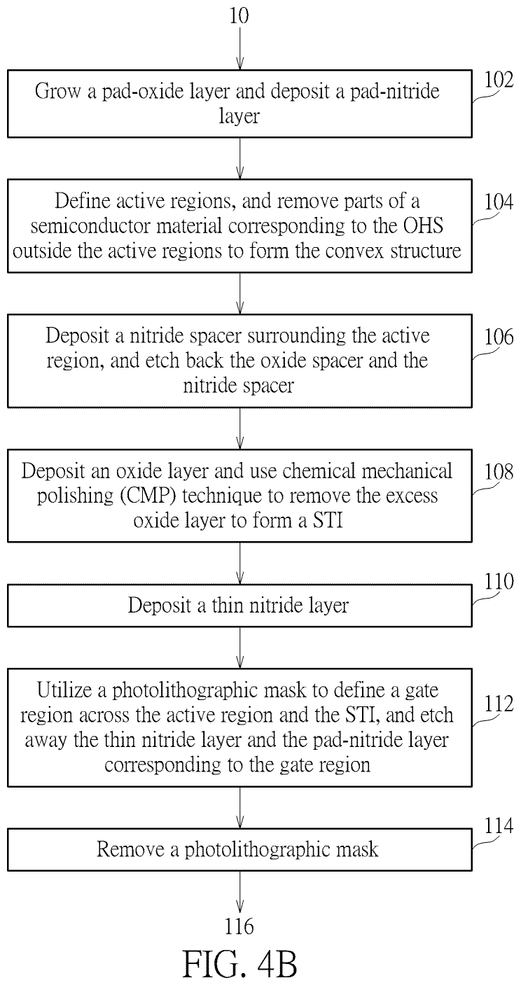

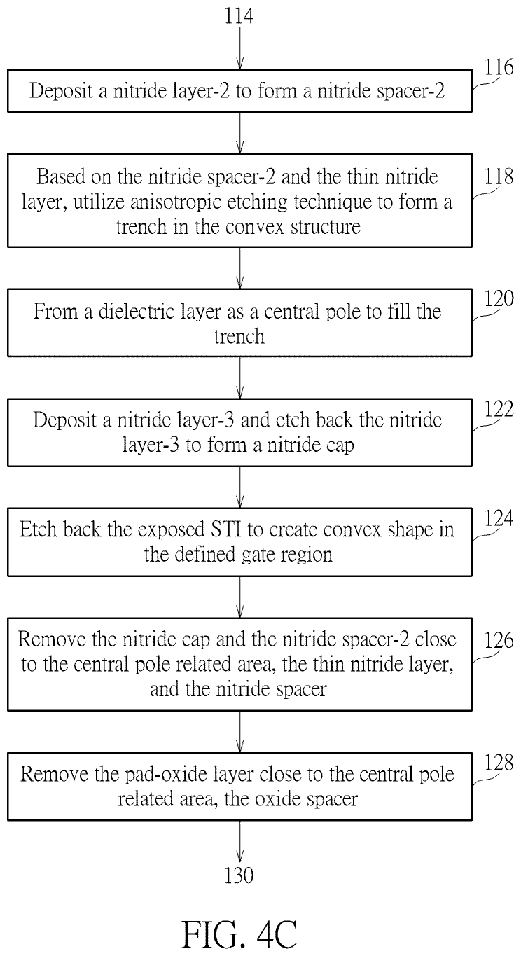

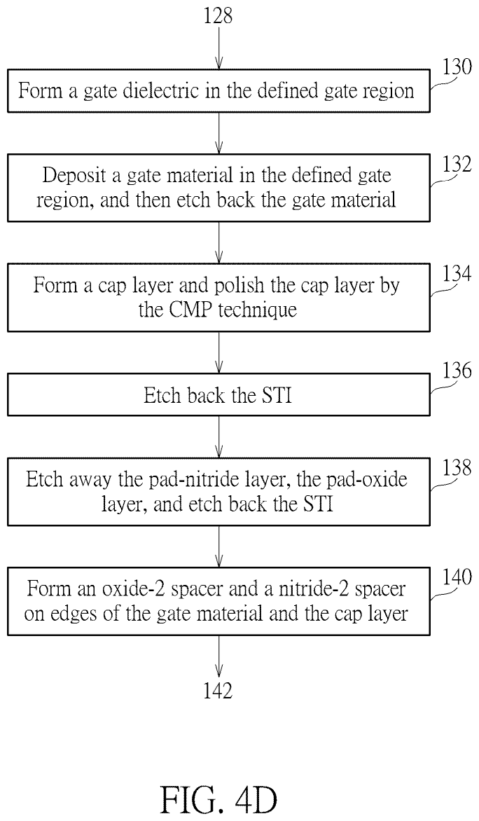

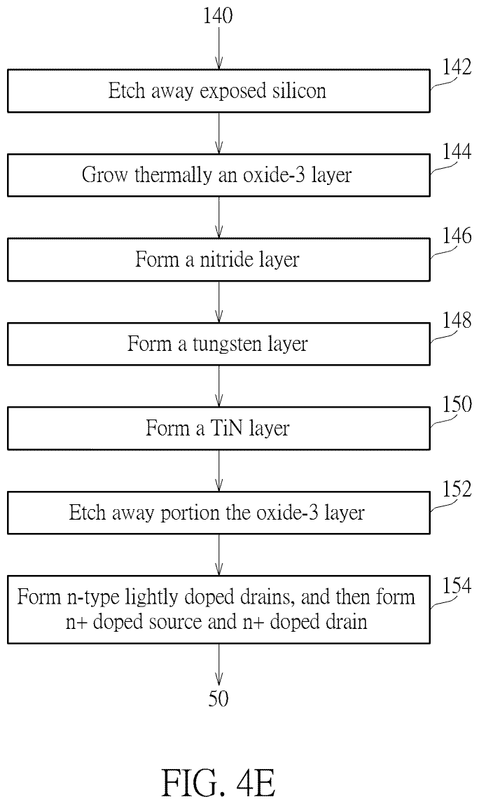

Please refer to FIGS. 4A, 4B, 4C, 4D, 4E, 5, 6, 7, 8, 9, 10, 11, 12, 13, 14, 15, 16, 17, 18, 19, 20, wherein FIG. 4A is a flowchart illustrating a manufacturing method of a 3D convex field-effect transistor (3DCFET) according to one embodiment of the present invention, and the manufacturing method of the 3DCFET in FIG. 4A can make the 3DCFET have lower standby current, lower gate-induced drain leakage (GIDL) current and lower short channel effect (SCE), and form a solid wall to clamp an active region or a narrow convex structure of the 3DCFET. Detailed steps of manufacturing the 3DCFET (using N type as an example) are as follows:
Step 10: Start.
Step 20: Based on a p-type well 202, define an active region and form a convex structure with one trench filled with a central pole.
Step 30: Form a gate of the 3DCFET above an original horizontal surface (OHS) of the p-type well 202.
Step 40: Form a source and a drain of the 3DCFET.
Step 50: End.

Please refer to FIGS. 4B, 4C and FIGS. 5, 6, 7, 8, 9, 10, 11, 12, 13, 14. Step 20 could include:
Step 102: Grow a pad-oxide layer 204 and deposit a pad-nitride layer 206.
Step 104: Define active regions, and remove parts of a semiconductor material (such as silicon) corresponding to the OHS outside the active regions to form the convex structure.
Step 106: Deposit a nitride spacer 306 (or an oxide spacer 304 and the nitride spacer 306) surrounding the active region, and etch back the oxide spacer 304 and the nitride spacer 306.
Step 108: Deposit an oxide layer and use chemical mechanical polishing (CMP) technique to remove the excess oxide layer to form a STI 402.
Step 110: Deposit a thin nitride layer 802.
Step 112: Utilize a photolithographic mask 902 to define a gate region across the active region and the STI 402, and etch away the thin nitride layer 802 and the pad-nitride layer 206 corresponding to the gate region.
Step 114: Remove a photolithographic (PR) mask 902, wherein a central pole related area is defined within the active region.
Step 116: Deposit a nitride layer-2 to form a nitride spacer-2 1102.
Step 118: Based on the nitride spacer-2 1102 and the thin nitride layer 802, utilize anisotropic etching technique to form a trench 1202 in the convex structure.
Step 120: From a dielectric layer (such as a thermal oxide) as a central pole 1302 to fill the trench 1202.
Step 122: Deposit a nitride layer-3 and etch back the nitride layer-3 to form a nitride cap 1402.
Step 124: Etch back the exposed STI 402 to create convex shape in the defined gate region.
Step 126: Remove the nitride cap 1402 and the nitride spacer-2 1102 close to the central pole related area, the thin nitride layer 802, and the nitride spacer 306.
Step 128: Remove the pad-oxide layer 204 close to the central pole related area, the oxide spacer 304.

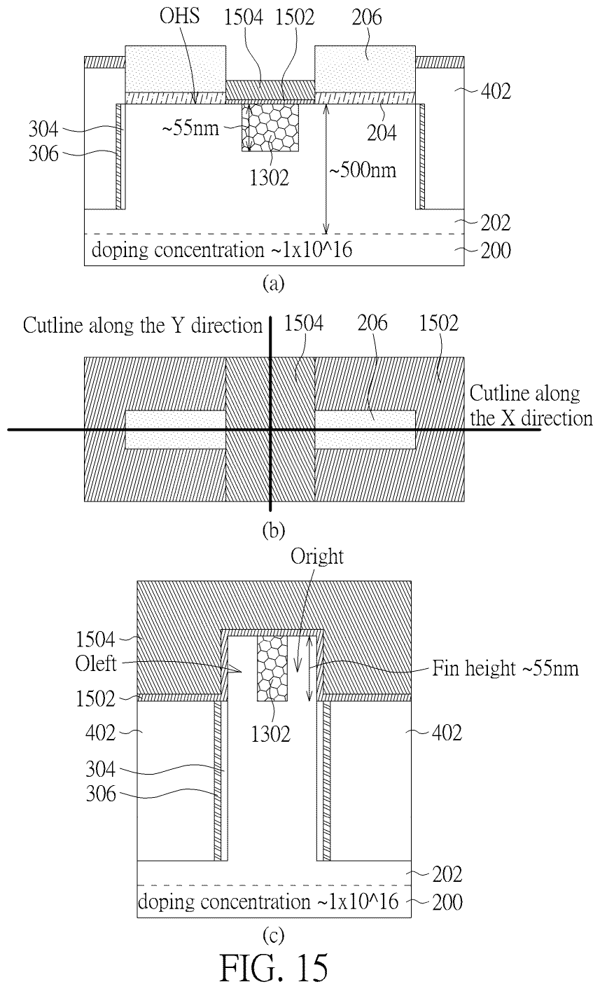

Please refer to FIG. 4D and FIGS. 15, 16, 17. Step 30 could include:
Step 130: Form a gate dielectric 1502 in the defined gate region.
Step 132: Deposit a gate material 1504 in the defined gate region, and then etch back the gate material 1504.
Step 134: Form a cap layer 1506 and polish the cap layer 1506 by the CMP technique.
Step 136: Etch back the STI 402.
Step 138: Etch away the pad-nitride layer 206, the pad-oxide layer 204, and etch back the STI 402.
Step 140: Form an oxide-2 spacer 1802 and a nitride-2 spacer 1804 on edges of the gate material 1504 and the cap layer 1506.

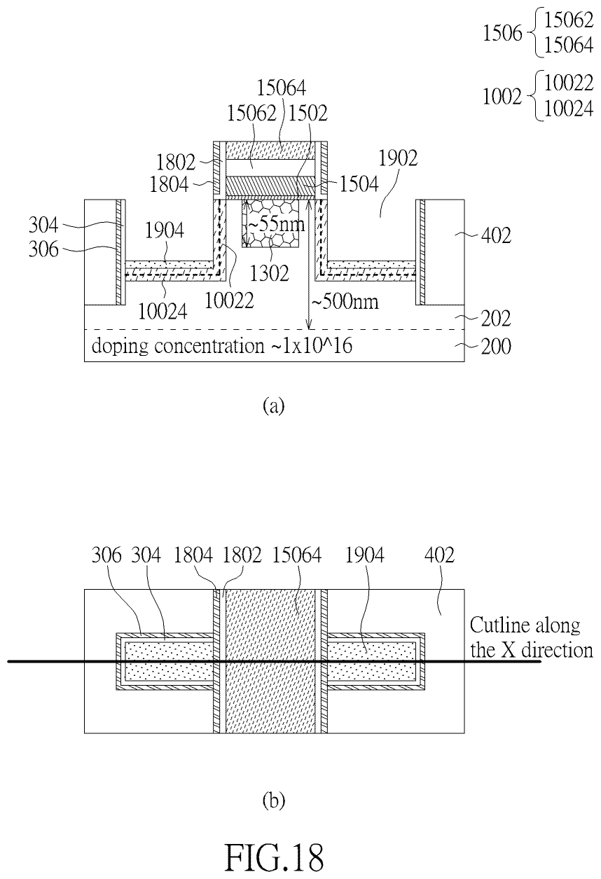

Please refer to FIG. 4E and FIGS. 18, 19, 20. Step 40 could include:
Step 142: Etch away exposed silicon.
Step 144: Grow thermally an oxide-3 layer 1002.
Step 146: Form a nitride layer 1904.
Step 148: Form a tungsten layer 1906.
Step 150: Form a TiN layer 1908.
Step 152: Etch away portion the oxide-3 layer 1002.
Step 154: Form n-type lightly doped drains (LDDs) 2004, 2006, and then form n+ doped source 2008 and n+ doped drain 2010.

Detailed description of the aforesaid manufacturing method is as follows. Using NMOS transistor for illustration purpose, start with the well-designed doped p-type well 202 installed in a p-type substrate 200 (wherein in another embodiment of the present invention, could start with the p-type substrate 200, rather than starting with the p-type well 202), wherein in one example the p-type well 202 has its top surface counted down about 500 nm thick from the OHS. In addition, for example, the p-type substrate 200 has concentration close to 1×10\hat{ }16 dopants/cm\hat{ }3. The actual dopant concentrations will be decided by final mass production optimizations.

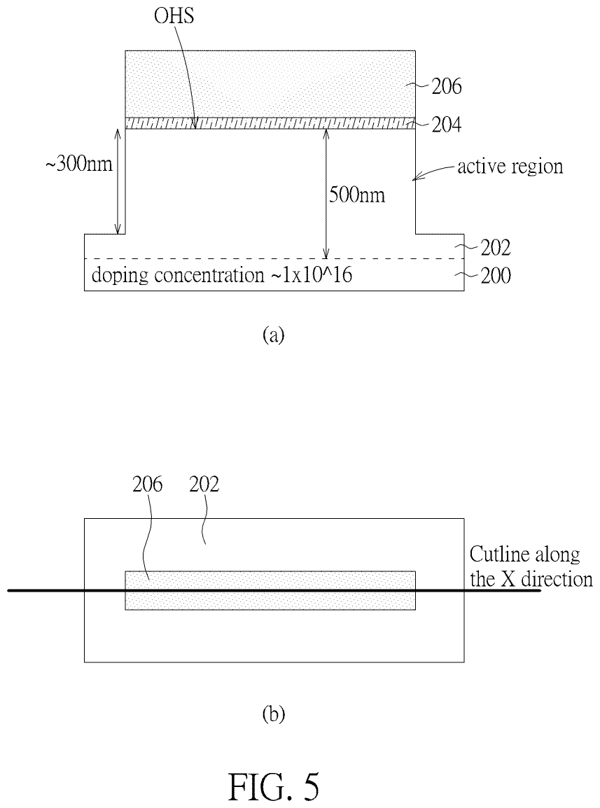

In Step 102, as shown in FIG. 5(a), grow the pad-oxide layer 204 with well-designed thickness over the OHS and deposit the pad-nitride layer 206 with well-designed thickness on a top surface of the pad-oxide layer 204.

In Step 104, as shown in FIG. 5(a), use a photolithographic masking technique to define the active regions of the 3DCFET by an anisotropic etching technique, wherein the anisotropic etching technique removes parts of a semiconductor material (such as silicon) outside the active regions to create the trench (e.g. about 300 nm deep) for future STI (shallow trench isolation) needs, such that a convex structure of the active region is created as well. In addition, FIG. 5(b) is a top view corresponding to FIG. 5(a), wherein FIG. 5(a) is a cross-section view along a cutline of an X direction shown in FIG. 5(b).

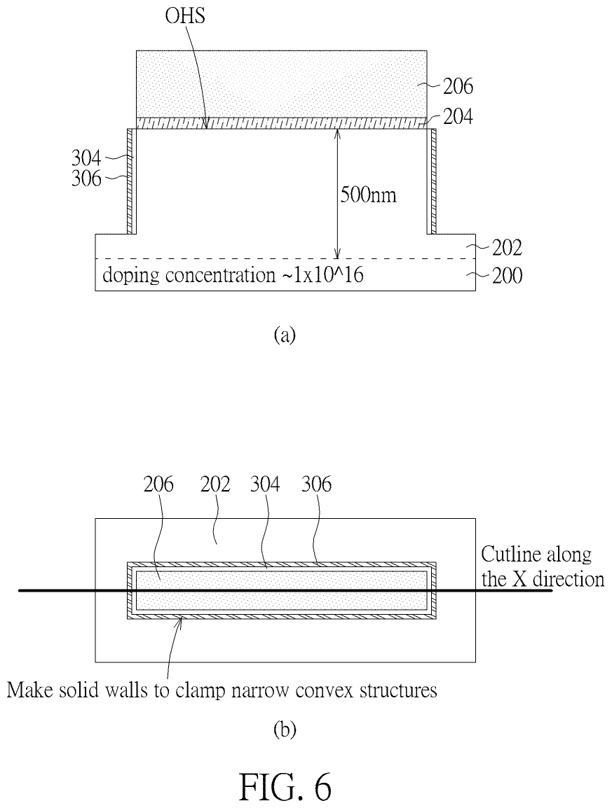

In Step 106, as shown in FIG. 6(a), deposit the oxide spacer 304 on the edge of the active region and the nitride spacer 306 on the oxide spacer 304, and use the anisotropic etching technique to etch back the oxide spacer 304 and the nitride spacer 306 to make top surfaces of the oxide spacer 304 and the nitride spacer 306 are in level up to the OHS, wherein the oxide spacer 304 and the nitride spacer 306 are outside the active region of the proposed 3DCFET. Thus, the key point here is that the oxide spacer 304 and then the nitride spacer 306 form a solid wall to clamp the active region or the narrow convex structure, especially the sidewalls of the convex structure. The solid clamping wall could be a single layer (such as nitride spacer) or other composite cap layers to protect the narrow convex or fin structure from collapse during the forming the source/the drain or the gate of the 3DCFET.

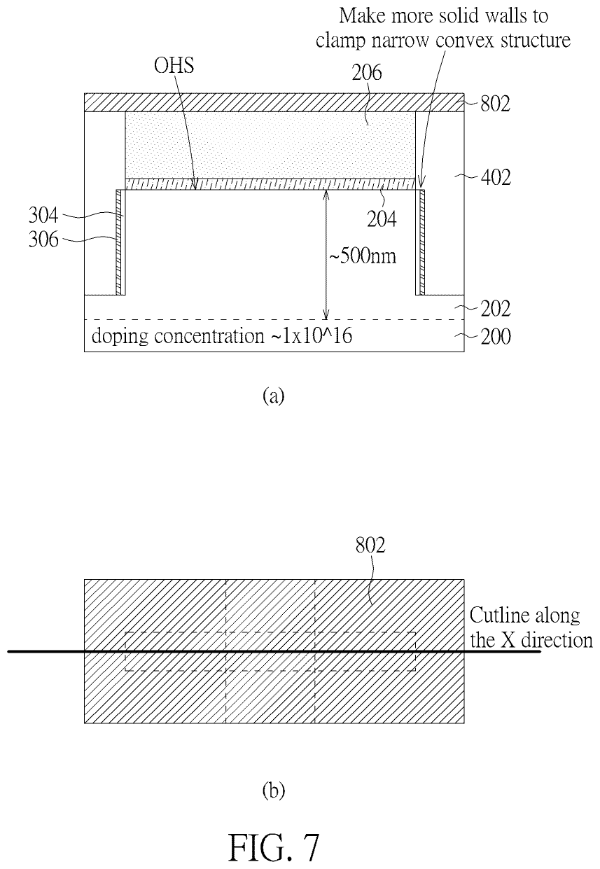

In Step 108, as shown in FIG. 7(a), deposit the thick oxide layer to fully fill the trench surrounding the active region and use the CMP technique to remove the excess oxide layer to form the STI 402, wherein a top surface of the STI 402 is in level up to a top surface of the pad-nitride layer 206. Again, the STI 402 further encompass or clamp the active region or the narrow convex structure, especially the sidewalls of the convex or fin structure, to protect the narrow convex structure from collapse during the forming the source/the drain or the gate of the 3DCFET.

In Step 110, as shown in FIG. 7(a), deposit the thin nitride layer 802 over the pad-nitride layer 206 and the STI 402. In addition, FIG. 7(b) is a top view corresponding to FIG. 7(a), wherein FIG. 7(a) is a cross-section view along a cutline of an X direction shown in FIG. 7(b).

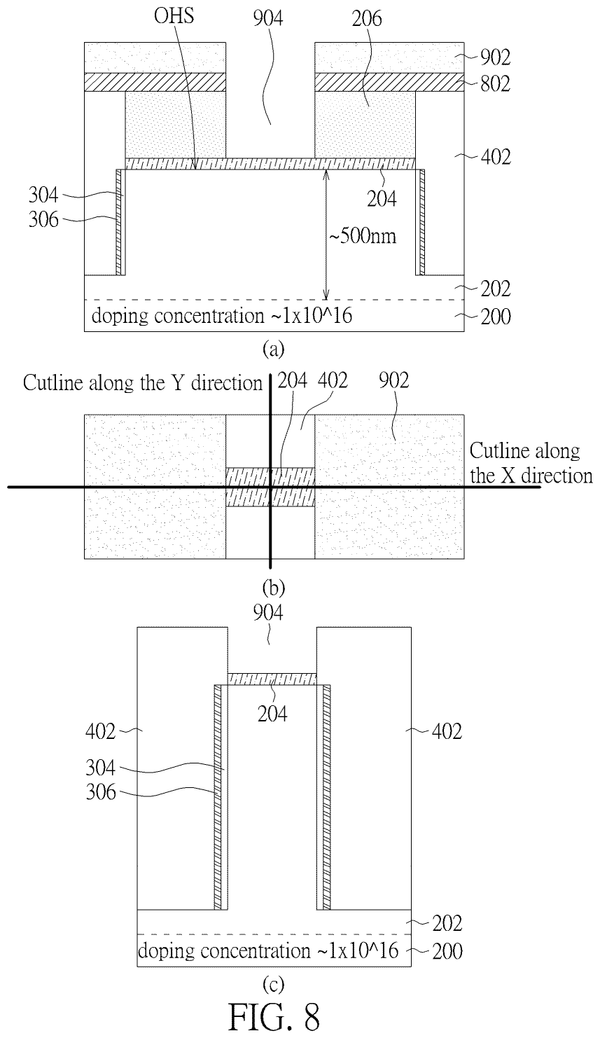

In Step 112, as shown in FIG. 8(a), utilize the photolithographic (PR) mask 902 to define the gate region across the active region and the STI 402 so that the thin nitride layer 802 and the pad-nitride layer 206 corresponding to the gate region are removed to create the concave 904. In addition, FIG. 8(b) is a top view corresponding to FIG. 8(a), wherein FIG. 8(a) is a cross-section view along a cutline of an X direction shown in FIG. 8(b) and FIG. 8(c) is a cross-section view along a cutline of a Y direction shown in FIG. 8(b).

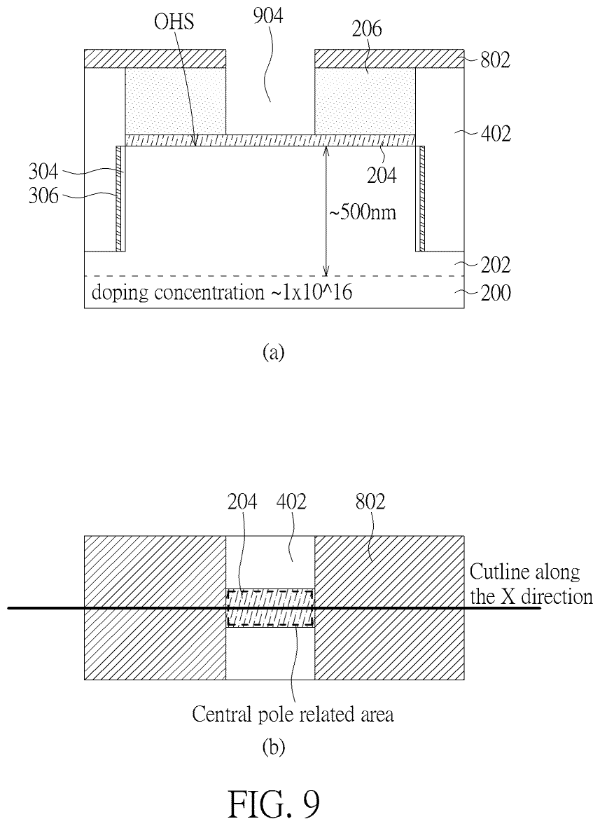

In Step 114, as shown in FIG. 9(a), remove the photolithographic (PR) mask 902. Thus, smooth edges along the thin nitride layer 802 and the pad-nitride layer 206 for the gate region of the 3DCFET is provided, and a central pole related area is also defined. In addition, FIG. 9(b) is a top view corresponding to FIG. 9(a), wherein FIG. 9(a) is a cross-section view along a cutline of an X direction shown in FIG. 9(b).

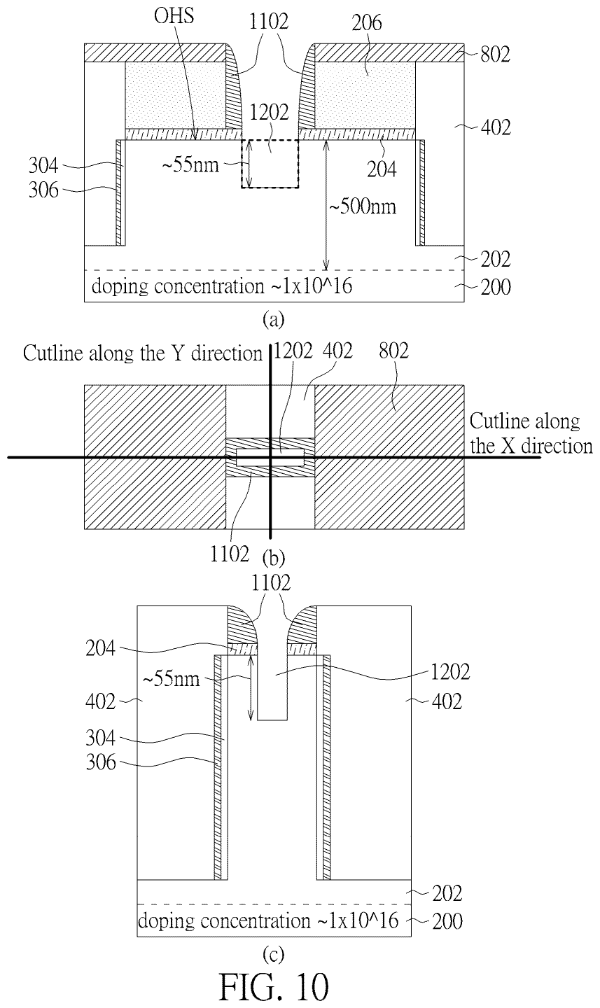

In Step 116, as shown in FIG. 10(a), the nitride layer-2 (or a combination of oxide/nitride layer) is deposited within the central pole related area and is etched back to form the nitride spacer-2 1102 (wherein for example, a width of the nitride spacer-2 1102 could be 1˜3 nm). As shown in FIG. 10(b), the nitride spacer-2 1102 on four surrounding edges inside the central pole related area, and the nitride spacer-2 1102 protects the original silicon regions underneath, which are critical to become a surrounding ring of silicon on the future created central pole, named as SRS-CP.

In Step 118, as shown in FIG. 10(a), then based on the nitride spacer-2 1102, use the anisotropic etching technique to etch the pad-oxide layer 204 corresponding to the central pole related area to form the trench 1202 with a depth around 50˜60 nm (e.g. 55 nm) in the exposed silicon region. That is, the nitride spacer-2 1102 acts as a mask such that the exposed pad-oxide layer 204 corresponding to the central pole related area could be removed, so is the exposed silicon at the central pole related area by approximately 55 nm deep, to create the trench 1202 at the central pole related area. The nitride spacer-2 1102 works like an awning to protect the SRS-CP to be created. In addition, FIG. 10(b) is a top view corresponding to FIG. 10(a), wherein FIG. 10(a) is a cross-section view along a cutline of an X direction shown in FIG. 10(b) and FIG. 10(c) is a cross-section view along a cutline of a Y direction shown in FIG. 10(b).

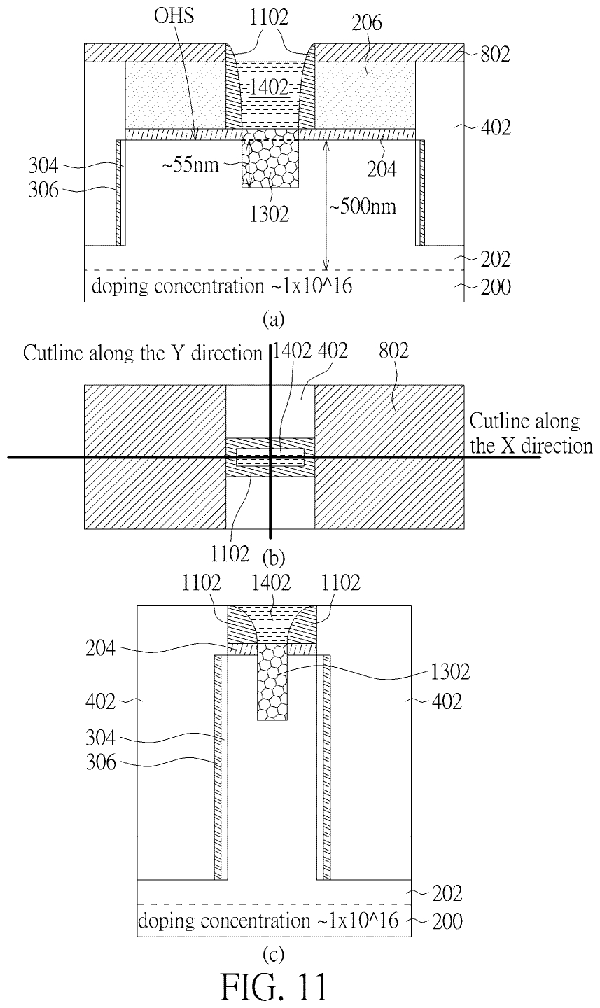

In Step 120, as shown in FIG. 11(a), form a dielectric layer (such as, perform short-time growth of the thermal oxide, or chemical vapor deposition (CVD) deposition) to fill the trench 1202 with a central pole 1302, or called as central pole or column pole (CP). The central pole or column pole can minimize the OFF state current (IOFF) in the future channel region of the 3DCFET such that the leakage current during the OFF state is dramatically reduced. The central pole 1302 could be made of other composite material to block the IOFF.

In Step 122, as shown in FIG. 11(a), then deposit the nitride layer-3 and etch back the nitride layer-3 to form the nitride cap 1402 over the central pole to protect the central pole. In addition, FIG. 11(b) is a top view corresponding to FIG. 11(a), wherein FIG. 11(a) is a cross-section view along a cutline of an X direction shown in FIG. 11(b) and FIG. 11(c) is a cross-section view along a cutline of a Y direction shown in FIG. 11(b).

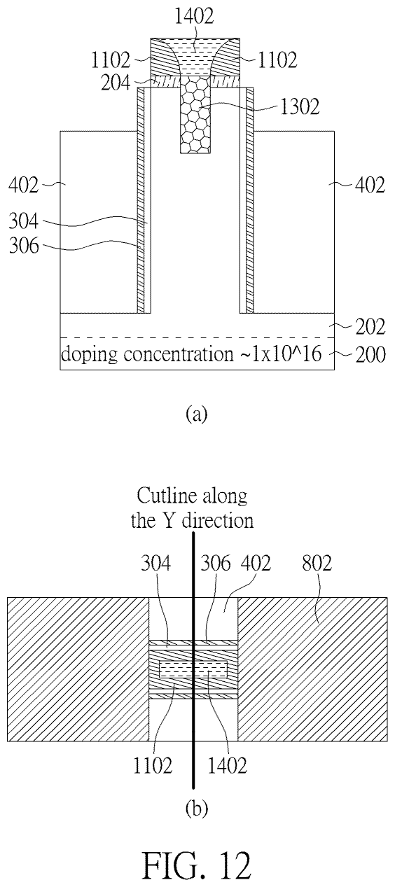

In Step 124, as shown in FIG. 12(a), etch back the exposed STI 402 by a depth about 50˜55 nm or 50˜75 nm to create the convex or fin shape in the defined gate region. In addition, FIG. 12(b) is a top view corresponding to FIG. 12(a), wherein FIG. 12(a) is a cross-section view along a cutline of a Y direction shown in FIG. 12(b).

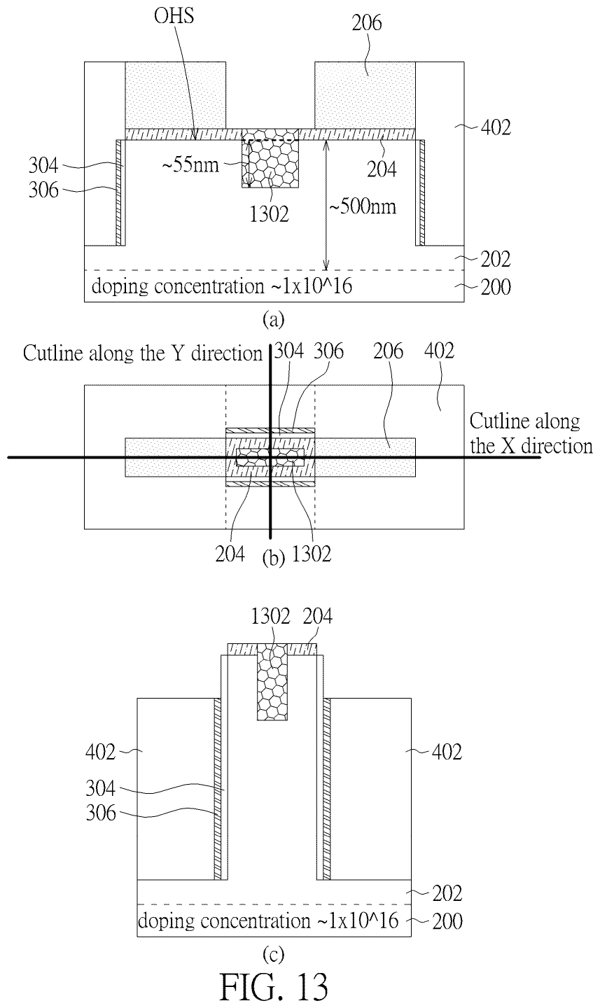

In Step 126, as shown in FIG. 13(a), use etching to remove the nitride cap 1402 and the nitride spacer-2 1102 in the central pole related area, the thin nitride layer 802, and the nitride spacer 306 covering the convex shape in the defined gate region. Thus, the previously defined central pole related area is shown again. In addition, FIG. 13(b) is a top view corresponding to FIG. 13(a), wherein FIG. 13(a) is a cross-section view along a cutline of an X direction shown in FIG. 13(b) and FIG. 13(c) is a cross-section view along a cutline of a Y direction shown in FIG. 13(b).

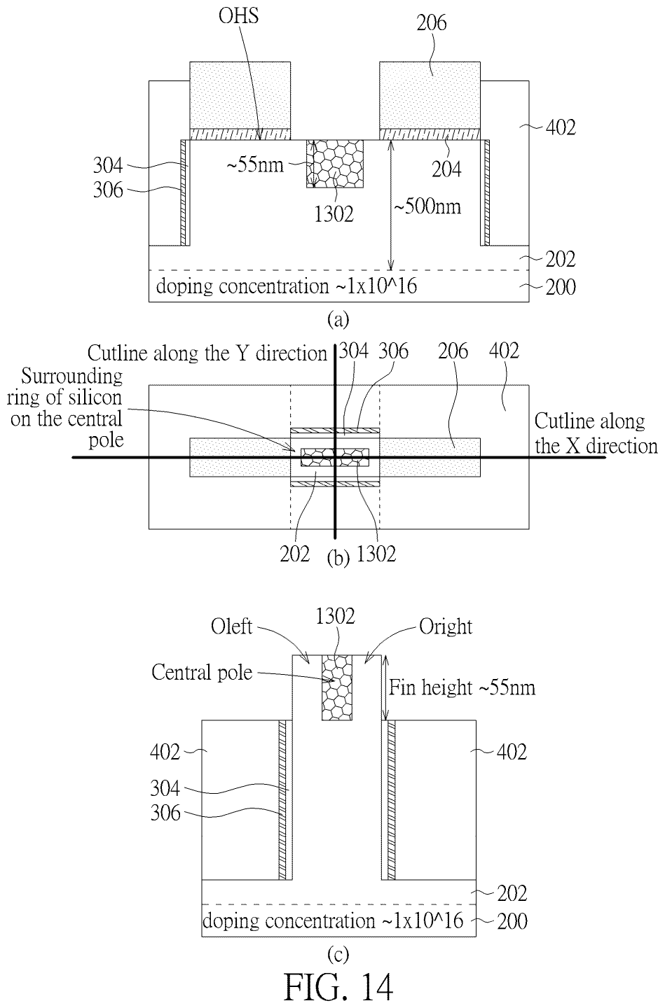

In Step 128, as shown in FIG. 14(a), use etching to remove the pad-oxide layer 204 in the central pole related area and the oxide spacer 304 covering the convex shape. Moreover, the STI 402 corresponding to the gate region is also etched down by a certain amount (e.g. 40˜80 nm deep) and the top surface of the STI 402 is lower than the top surface of the pad-nitride layer 206. Thus, as shown in FIG. 14(c), two sides of single crystalline silicon of the convex shape are exposed. More importantly, as shown in FIG. 14(c), the central pole (CP) is in the convex structure or active region, and such central pole (CP) within the convex or fin structure can effectively minimize the leakage current path during the OFF state of the proposed 3DCFET. However, in the convex or fin structure, there are still two vertical thin silicon sheets Oright, Oleft for current conduction during the ON state of the 3DCFET. The two exposed thin silicon sheets Oright, Oleft on the right side and left side of the central pole could be called thin-sheets of silicon layers on two sides of central pole. Moreover, as shown in FIG. 14(b), there is a surrounding ring of silicon on the central pole (SRS-CP). In addition, FIG. 14(b) is a top view corresponding to FIG. 14(a), wherein FIG. 14(a) is a cross-section view along a cutline of an X direction shown in FIG. 14(b) and FIG. 14(c) is a cross-section view along a cutline of a Y direction shown in FIG. 14(b).

In Step 130, as shown in FIG. 15(a), form the gate dielectric 1502 (such as high K dielectric materials or oxide).

In Step 132, as shown in FIG. 15(a), subsequently deposit the gate material (such as polysilicon or metal like Tungsten over TiN layer) 1504 in the defined gate region, use the CMP technique to remove the excess gate material 1504, and then etch back the gate material 1504. In addition, FIG. 15(b) is a top view corresponding to FIG. 15(a), wherein FIG. 15(a) is a cross-section view along a cutline of an X direction shown in FIG. 15(b) and FIG. 15(c) is a cross-section view along a cutline of a Y direction shown in FIG. 15(b).

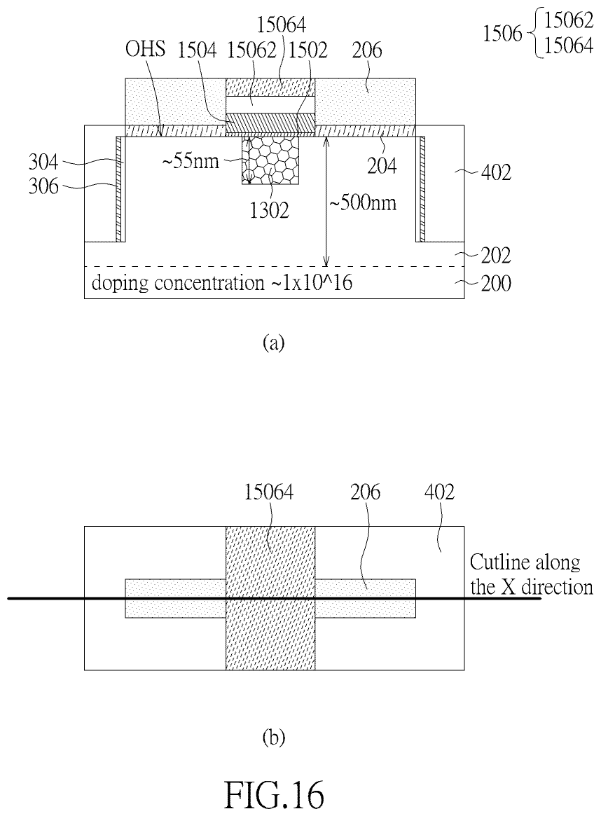

In Step 134, as shown in FIG. 16(a), then deposit the composite cap layer 1506 which could be composed of a nitride-1 layer 15062 and a Hardmask-oxide layer 15064 into the gate region on a top surface of the gate material 1504, wherein the composite cap layer 1506 is used for protecting the gate material 1504. Then, the composite cap layer 506 is polished by the CMP technique to make a top surface of the composite cap layer 1506 in level up to the top surface of the pad-nitride 206.

In Step 136, as shown in FIG. 16(a), then etch the STI 402 to make a top surface of the STI 402 in level up to the top surface of the pad-oxide layer 204. In addition, FIG. 16(b) is a top view corresponding to FIG. 16(a), wherein FIG. 16(a) is a cross-section view along a cutline of an X direction shown in FIG. 16(b).

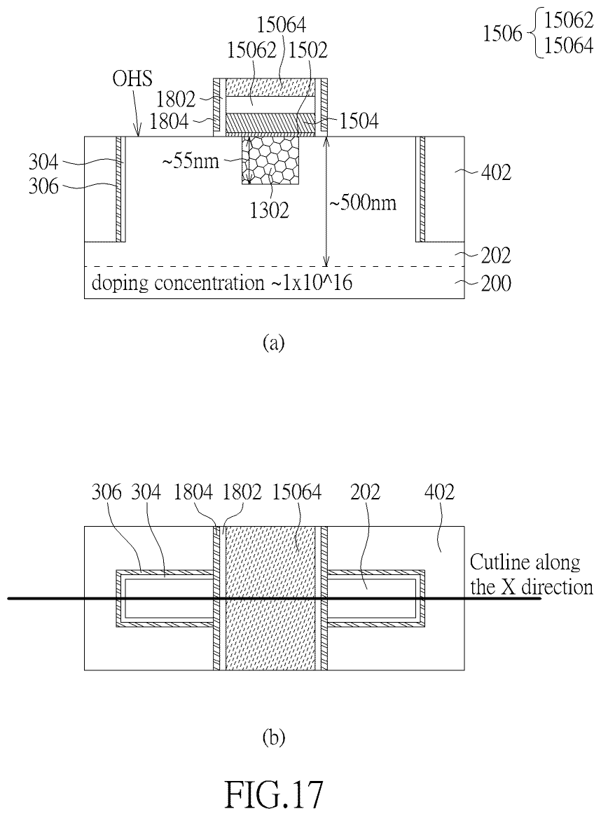

In Step 138, as shown in FIG. 17(a), etch away the pad-nitride layer 206, the pad-oxide layer 204, and etch back some portion of the STI 402 to reveal the OHS and to make the top surface of the STI 402 in level up to the OHS.

In Step 140, as shown in FIG. 17(a), then deposit an oxide-2 layer to form the oxide-2 spacer 1802 and a nitride-2 layer to form the nitride-2 spacer 1804 on the edges of the gate material 1504 and the composite cap layer 506. In addition, FIG. 17(b) is a top view corresponding to FIG. 17(a), wherein FIG. 17(a) is a cross-section view along a cutline of an X direction shown in FIG. 17(b).

In Step 142, as shown in FIG. 18(a), then etch away some exposed silicon areas in the active region to create shallow trenches 1902 for the source and the drain (e.g. about 50 nm deep) of the 3DCFET.

In Step 144, as shown in FIG. 18(a), use a thermal oxidation process, called as an oxidation-3 process, to grow the oxide-3 layer 1002 (including both an oxide-3V layers 10022 penetrating vertical sidewalls of the bulk body of the semiconductor material (assuming with a sharp crystalline orientation (110)) and an oxide-3B layers 10024 over the bottom of the shallow trenches 902). Since one sidewall of the shallow trenches 1902 have vertical composite materials of the oxide-2 spacer 1802 and the nitride-2 spacer 1804, and the other sidewalls of the shallow trenches 1902 is against the oxide spacer 304 and the nitride spacer 306, the oxidation-3 process should grow little oxide (i.e. the oxide-3 layer 1002) on these walls such that a width of the source/drain of the proposed 3DCFET is not really affected by the thermal oxidation process. In addition, a thickness of the oxide-3V layer 10022 and the oxide-3B layer 10024 drawn in FIG. 18 and following figures are only shown for illustration purpose, and its geometry is not proportional to the dimension of the STI 402 shown in those figures. For example, the thickness of the oxide-3V layer 10022 and the oxide-3B layer 10024 is around 20˜30 nm, but the vertical height of the STI 402 could be around 200˜250 nm.

Based on the oxidation-3 process, the thickness of oxide-3V layer 10022 can be very accurately controlled under both precisely controlled thermal oxidation temperature, timing and growth rate. Since the thermal oxidation over a well-defined silicon surface should result in that 40% of the thickness of the oxide-3V layer 10022 is taken away the thickness of the exposed (110) silicon surface in the vertical wall of the bulk body of the transistor and the remaining 60% of the thickness of the oxide-3V layer 10022 is counted as an addition outside the vertical wall of the bulk body of the transistor (such a distribution of 40% and 60% on the oxide-3V layer 10022 relative to the oxide-2 spacer 1802/the nitride-2 spacer 1804 is particularly drawn clearly by dash-lines in FIG. 18).

In Step 146, as shown in FIG. 18(a), use CVD to deposit nitride on a top surface of the oxide-3B layer 10024 and etch back the nitride to form the nitride layer 1904. In addition, FIG. 18(b) is a top view corresponding to FIG. 18(a), wherein FIG. 18(a) is a cross-section view along a cutline of an X direction shown in FIG. 18(b).

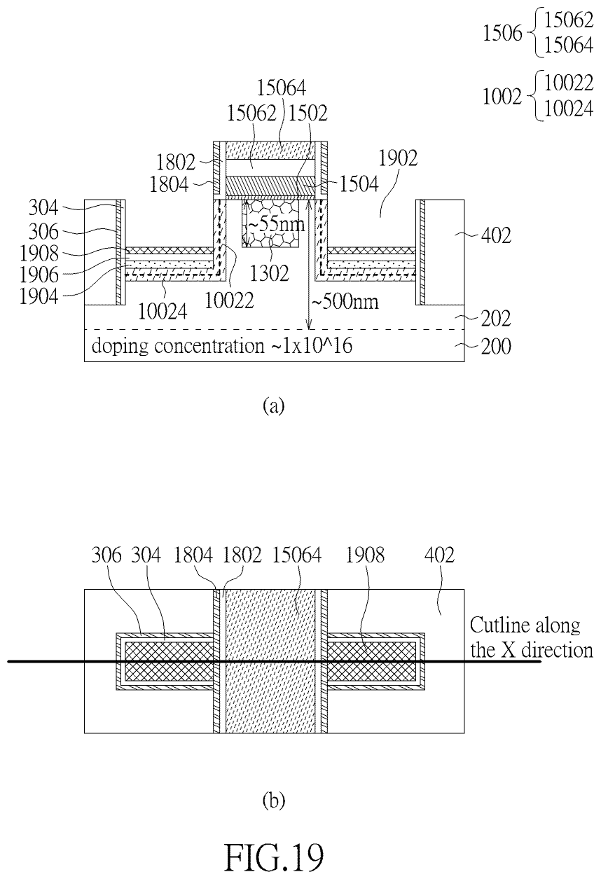

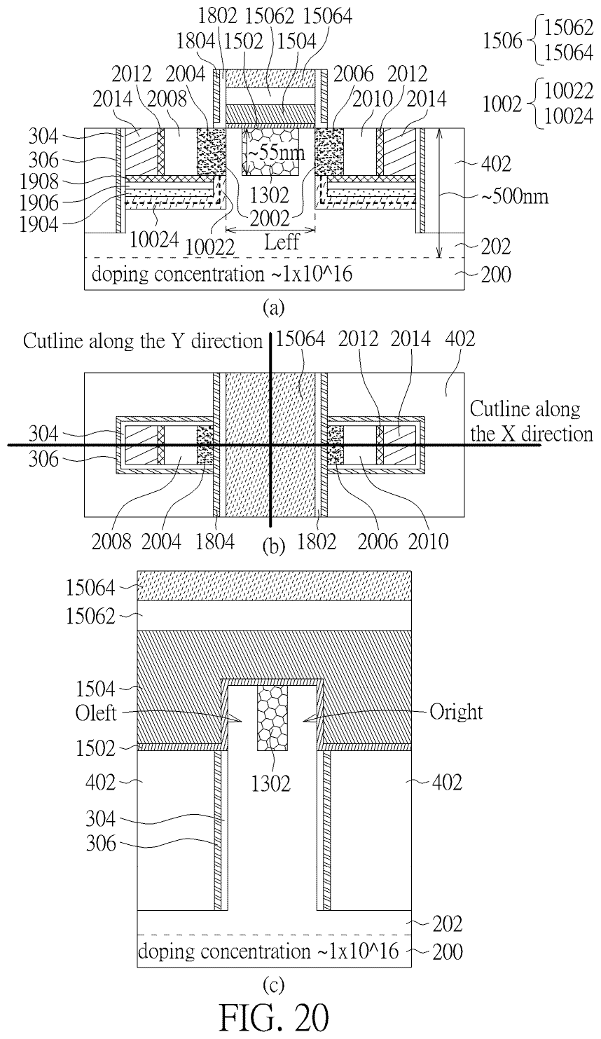

In Step 148, as shown in FIG. 19(a), deposit tungsten and etch back tungsten to form the tungsten layer 1906 on a top surface of the nitride layer 1904.

In Step 150, as shown in FIG. 19(a), then deposit (such as, Atomic Layer Deposition, ALD) TiN and etch back TiN to form the TiN layer 1908 above a top surface of the tungsten layer 1906. In addition, FIG. 19(b) is a top view corresponding to FIG. 19(a), wherein FIG. 19(a) is a cross-section view along a cutline of an X direction shown in FIG. 19(b).

In Step 152, as shown in FIG. 20(a), then use a top surface of the TiN layer 1908 as reference to etch away the portion of the oxide-3V layer 10022 to reveal silicon sidewalls 2002 (with the crystalline orientation (110) of the silicon region).

In another example, the steps to form the tungsten layer 1906 and the TiN layer 1908 in FIG. 19 could be omitted, and etching the portion of the oxide-3V layer 10022 in FIG. 20 could use the top surface of the nitride layer 1904 as reference.

In Step 154, as shown in FIG. 20(a), then use the selective growth technique (such as selective epitaxy growth (SEG) technique) to form the n-type LDDs 2004, 2006 and then the n+ doped source 2008 and n+ doped drain 2010. It is worth mentioning that no ion-implantations for forming all n-type LDDs 2004, 2006, the n+ doped source 2008, and n+ doped drain 2010 of the proposed 3DCFET are needed and no high temperature thermal annealing is necessary to remove those damages due to heavy bombardments of forming the n+ doped source 2008 and n+ doped drain 2010.

In Step 156, as shown in FIG. 20(a), finally, deposit the TiN layer 2012 and the Tungsten layer 2014 (such as, could be carried out by Atomic Layer Deposition) and etch back the TiN layer 2012 and the Tungsten layer 2014. In addition, FIG. 20(b) is a top view corresponding to FIG. 20(a), wherein FIG. 20(a) is a cross-section view along a cutline of an X direction shown in FIG. 20(b) and FIG. 20(c) is a cross-section view along a cutline of a Y direction shown in FIG. 20(b). Furthermore, metal plugs (not shown) could be deposited on and contacted to the top surface of the n+ doped source 2008 and n+ doped drain 2010, respectively.

As mentioned, it is possible to increase a depth of an oxide region (non-conductive region) or the central pole to reduce more IOFF current. For example, a bottom of the oxide region or the central pole is lower than a bottom of the oxide-3B layers 10024. In summary, there is a central pole or a non-conductive region in the convex structure or active region and the central pole is encompassed by the surrounding ring of silicon. Such the central pole within the convex structure can effectively suppress the leakage current path during the OFF state of the proposed 3DCFET. However, the convex or fin structure still has two vertical silicon sheets Oright, Oleft for current conduction during the ON state of the 3DCFET. In addition, for example, the width of the vertical silicon sheet Oright (or the vertical silicon sheet Oleft) could be around 1.5˜5 nm. Since the central pole is encompassed by the surrounding ring of silicon, thus a conductive current through the conductive channel region during an ON state of the proposed 3DCFET is first converged in one edge portion of the surrounding ring of silicon extending from a first conduction region (such as, the n+ doped drain 2010) of the proposed 3DCFET, then diverged due to the existence of the central pole, and then converged in the another edge portion of the surrounding ring of silicon extending from a second conductive region (such as the n+ doped source 2008) of the proposed 3DCFET. Moreover, the solid fence wall (such as the oxide spacer 304 and then the nitride spacer 306 shown in FIG. 6) is formed to clamp the active region or the narrow convex structure, especially the sidewalls of the convex structure. The solid wall could be a single layer or other composite layers to protect the narrow convex structure from collapse during the forming the source/the drain or the gate of the 3DCFET. Furthermore, the STI 402 (shown in FIG. 7) further encompass or clamp the active region or the narrow convex structure, especially the sidewalls of the convex structure, to protect the narrow convex structure from collapse during the forming the source/the drain or the gate of the proposed 3DCFET. Thus, even the height of the convex or fin structure (such as 60˜300 nm) is far larger than the width of the convex or fin structure (such as 3˜7 nm) of the proposed 3DCFET, the convex structure protected by the solid wall of the present invention is unlikely vulnerable during the following processes (such as the source/the drain formation, gate formation, etc.). Another advantage of the present invention is that, since the thickness of the oxide-2 spacer 1802 and the nitride-2 spacer 1804 formed on the edges of the gate region (shown in FIG. 17) is controllable, and the thickness of the oxide-3V layer 10022 and the oxide-3B layer 10024 (shown in FIG. 18) made by the thermal oxidation process is controllable as well, the edge of the source/the drain could be aligned or substantially aligned with the edge of the gate region (as shown in FIG. 20), especially the source/the drain is formed by the SEG technique. Thus, according to the present invention, the relative position or distance between the edge of the source/the drain and the edge of the gate region is controllable, and could be dependent on the thickness of spacer formed on the edges of the gate region and/or the thickness of the oxide layer (such as the oxide-3V layer 10022). Therefore, an effective channel length Leff (shown in FIG. 20) could be controlled such that the gate-induced drain leakage (GIDL) current issue could be improved.

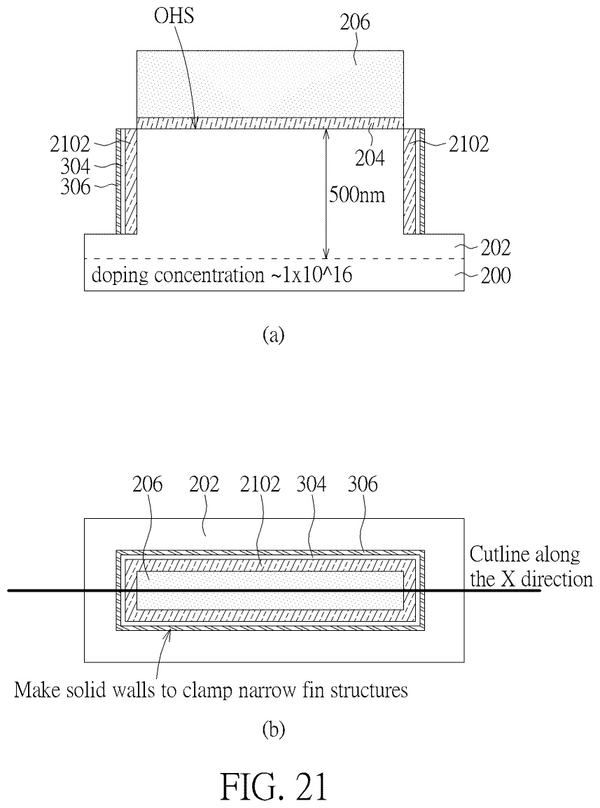

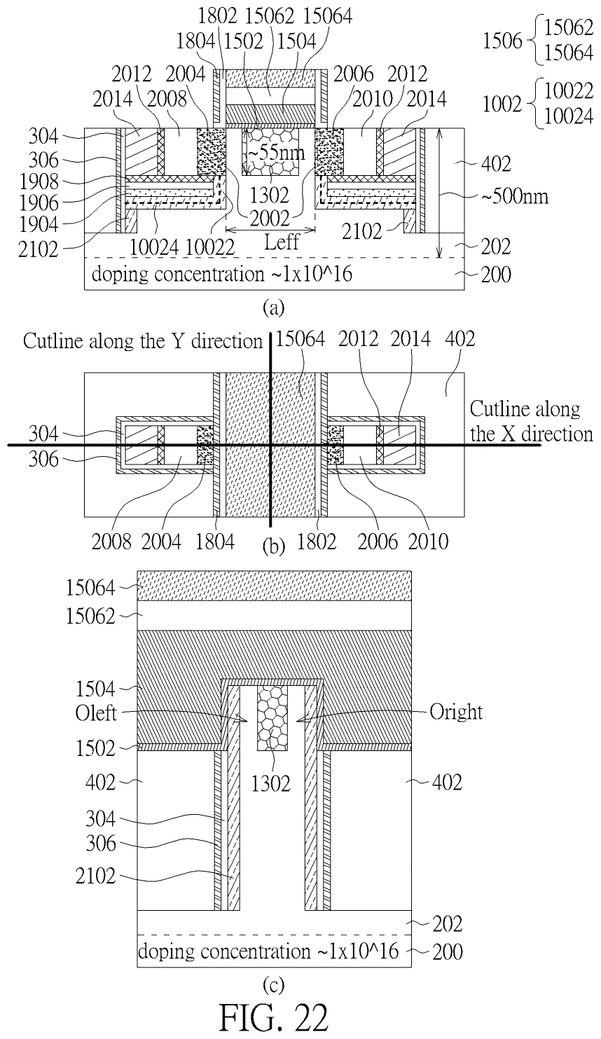

In addition, in another embodiment of the present invention, as shown in FIG. 21, a selective growth semiconductor layer 2102 (such as selective epitaxy growth Si, SiGe, etc.) could be formed to increase the fin width of the convex structure before the oxide spacer 304 and the nitride spacer 306 clamping the active region. The advantage of FIG. 21 is that, the fin width of the convex structure could be extended and controlled for better current transmission in ON state of another proposed 3DCFET. Later on, similar processes described in FIGS. 7, 8, 9, 10, 11, 12, 13, 14, 15, 16, 17, 18, 19, 20 could be applied to the structure in FIG. 21. In addition, FIG. 21(b) is a top view corresponding to FIG. 21(a), wherein FIG. 21(a) is a cross-section view along a cutline of an X direction shown in FIG. 21(b).

Thus, a structure of the another proposed 3DCFET is completed and shown in FIG. 22. In addition, FIG. 22(b) is a top view corresponding to FIG. 22(a), wherein FIG. 22(a) is a cross-section view along a cutline of an X direction shown in FIG. 22(b) and FIG. 22(c) is a cross-section view along a cutline of a Y direction shown in FIG. 22(b).

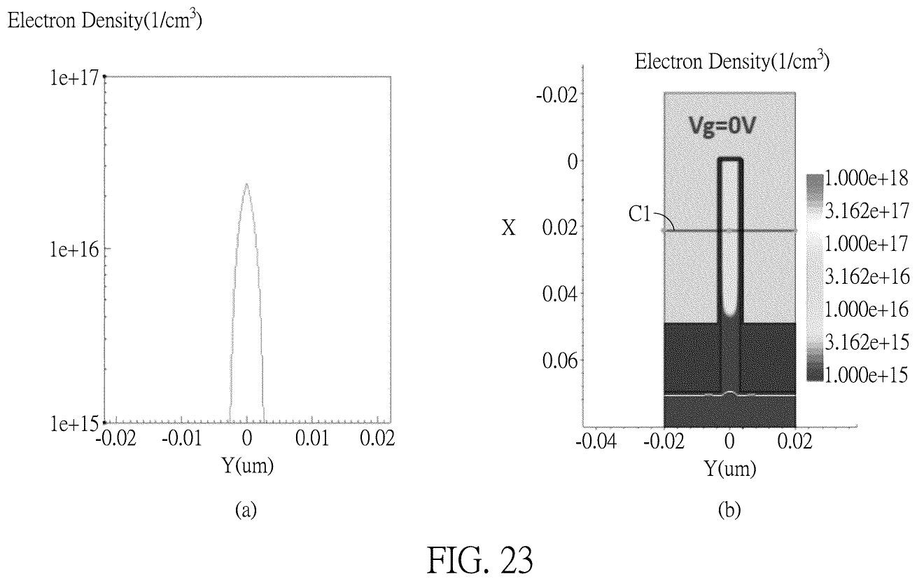

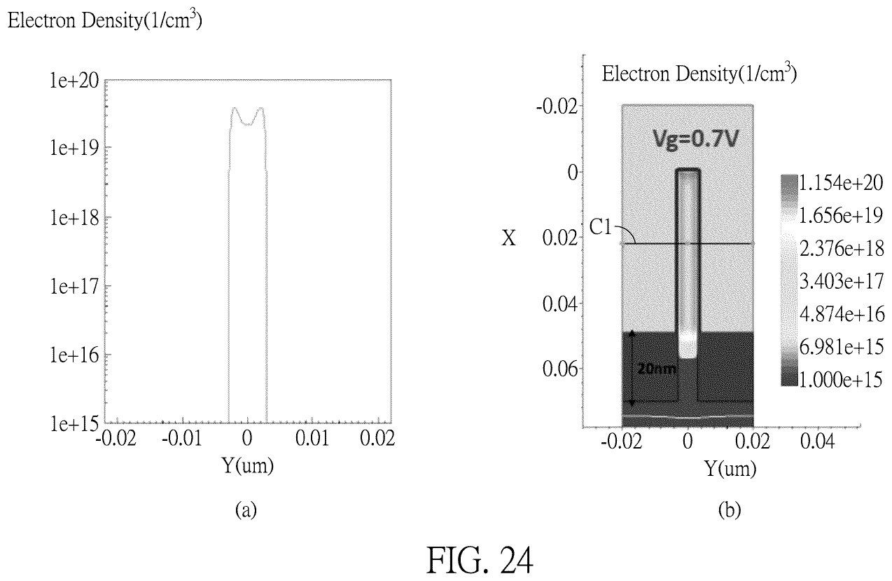

FIGS. 23, 24 shows the TCAD simulation results for the conventional FinFET which has 6 nm fin width, 50 nm fin height, 0.8 nm thickness gate oxide, 2×10¹⁵ channel doping concentration, and 1×10¹⁵ substrate doping concentration. With suitable gate metal material to adjust the work function, the peak electron density during the OFF state (Vg=0V) is around 2.5×10¹⁶/cm3 as shown in FIG. 23(a) and FIG. 23(b) illustrates the electron density distribution along the cross section of the conventional fin structure, wherein FIG. 23(a) corresponds to a cutline C1 of an X direction shown in FIG. 23(b). Meanwhile, the peak electron density during the ON state (Vg=0.7V) is around 3×10¹⁹/cm3 as shown in FIG. 24(a) and FIG. 24(b) illustrates the electron density distribution along the cross section of the conventional fin structure, wherein FIG. 24(a) corresponds to the cutline C1 of the X direction shown in FIG. 24(b). The ratio between the ON state peak electron density and OFF state peak electron density is around 3×10¹⁹/2.5×10¹⁶=1.2×10³.

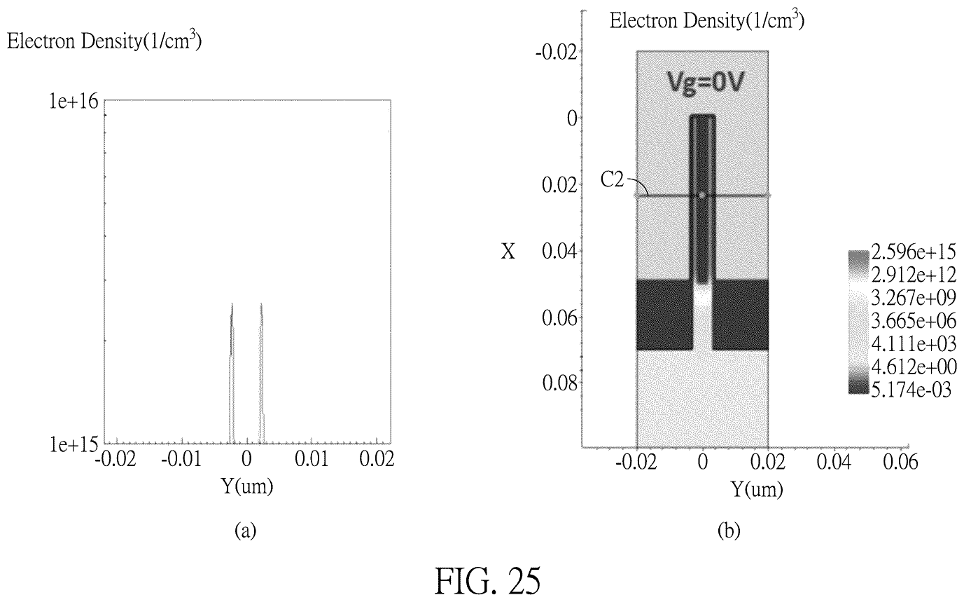

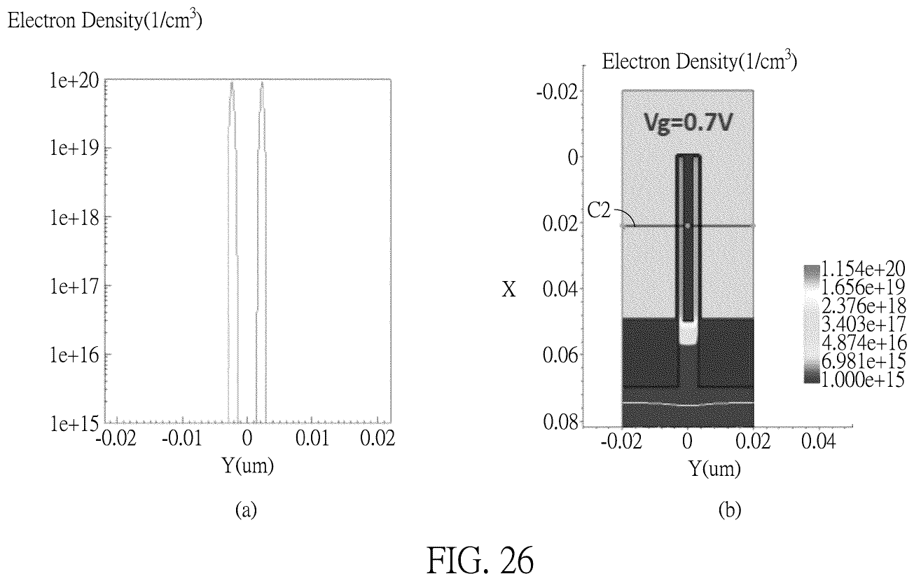

On the other hand, FIGS. 25, 26 shows the TCAD simulation results according to the present invention with central pole in convex structure which has 6 nm fin width, 50 nm fin height, 0.8 nm thickness gate oxide, 2×10¹⁵ channel doping concentration, 1×10¹⁵ substrate doping concentration, and a 3 nm central pole disposed in the 6 nm convex or fin width to separate two 1.5 nm width sub-fins. The peak electron density during the OFF state (Vg=0V) is around 2.7×10¹⁵/cm3 as shown in FIG. 25(a) and FIG. 25(b) illustrates the electron density distribution along the cross section of the convex structure with central pole according to the present invention), wherein FIG. 25(a) corresponds to a cutline C2 of the X direction shown in FIG. 25(b). Meanwhile, the peak electron density during the ON state (Vg=0.7V) is around 1×10²⁰/cm3 as shown in the right figure of FIG. 26(a) and FIG. 26(b) illustrates the electron density distribution along the cross section of the convex structure with central pole according to the present invention), wherein FIG. 26(a) corresponds to the cutline C2 of the X direction shown in FIG. 26(b). The ratio between the On-state peak electron density and Off-state peak electron density is around 1×10²⁰/2.7×10¹⁵=3.7×10⁴. Thus, the present invention effectively improve the lon/IOFF ratio about 30 times (3.7×10⁴/1.2×10³). Comparing with various transistor structures such as FinFET or Tri-gate designs, some IOFF's can be as large as 5 to 10 pA, the present invention could provide the transistor with 0.25˜0.5 pA. If a chip does integrate 1 trillion transistors on a die according to the present invention, then a total of one trillion of transistors will have its IOFF of a die is only approaching 0.25˜0.5 Amperes.

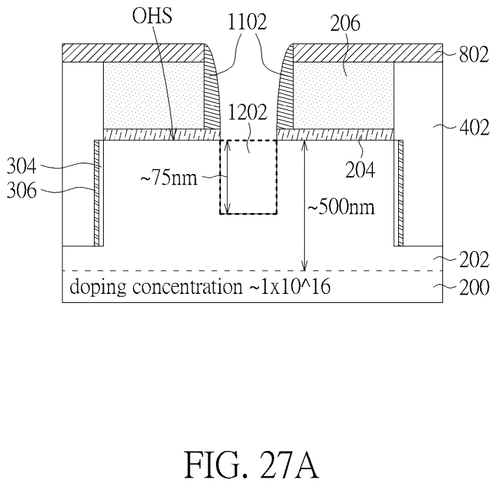

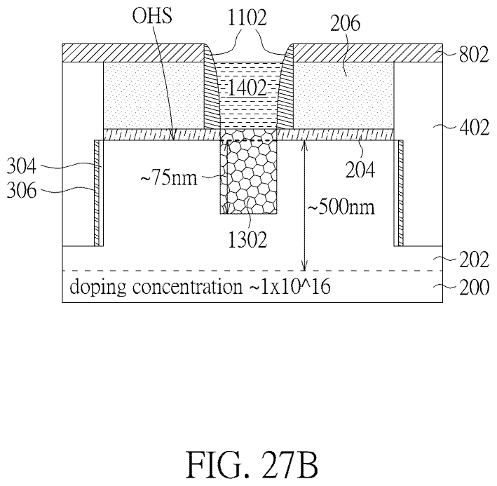

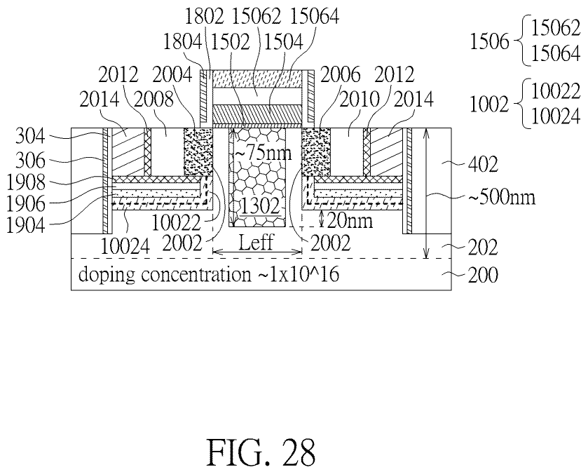

In addition, in another embodiment of the present invention, the trench 1202 corresponding to the central pole related area has a depth around 75 nm (shown in FIG. 27A) so that the central pole 1302 (shown in FIG. 27B) also has a depth around 75 nm. Thus, a corresponding 3DCFET with the central pole 1302 which has the depth around 75 nm is shown in FIG. 28, wherein it is noted that a bottom surface of the central pole 1302 is lower than a bottom surface of the oxide-3B layers 10024 20 nm. Furthermore, the bottom of the gate material (or gate conductive material) which is outside the convex or fin structure is lower than the bottom surface of the source or drain region, or lower than the bottom surface of the oxide-3B layers 10024.

According to the present invention:
(1) The leakage current path during the OFF state is reduced, due to the exist of the central pole or the non-conductive region in the convex structure or the channel region in the active region, and such a surrounding ring of silicon encompassing the central pole within the convex structure can effectively suppress the leakage current path during the OFF state of the proposed 3DCFET. Moreover, the convex structure of the present invention still has two vertical semiconductor sheets (i.e. Oright and Oleft, or thin-sheets of silicon layers on two sides of the central pole) for current conduction during the ON state of the proposed 3DCFET. In one example, each vertical silicon sheets may have a width of 1˜5 nm, such as 1.5, 2 or 3 nm. To increase the ON state current, additional elective growth semiconductor (such as Si or SiGe) layer could be formed to increase the fin width before forming the oxide spacer and the nitride spacer to clamp the active region.
(2) A solid wall is formed to clamp the active region or the narrow convex structure, especially the sidewalls of the convex structure. Thus, even the height of the convex structure (such as 60˜300 nm) is far larger than the width of the proposed 3DCFET structure (such as 3˜7 nm), the proposed 3DCFET structure protected by the sold wall of the present invention is unlikely vulnerable.
(3) The relative position or distance between the edge of the source/drain and the edge of the Gate region is controllable, and could be dependent on the thickness of spacer formed on the edges of the Gate and/or the thickness of the oxide layer (such as the oxide-3V layer).
(4) The resistance of the source/drain could be improved by forming metal-semiconductor junction in the source/drain.
(5) Most the source/drain areas are isolated by insulation materials including, the bottom structure by the Oxide-3B and/or nitride-3, the junction leakage can be significantly reduced.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A transistor structure comprising:
a substrate with a convex structure, wherein the convex structure has a conductive channel region;
a source region contacting with a first end of the conductive channel region;
a drain region contacting with a second end of the conductive channel region;
a trench formed in the convex structure and between the first end and the second end; and
a central pole in the trench, wherein a material of the central pole is different from that of the conductive channel region.

2. The transistor structure in claim 1, wherein the substrate is made of silicon, and the central pole is encompassed by a surrounding ring of silicon within the convex structure.

3. The transistor structure in claim 1, wherein the material of the central pole is a non-conductive material.

4. The transistor structure in claim 2, wherein the non-conductive material is oxide thermally grown in the trench.

5. The transistor structure in claim 1, further comprising:
a gate region crossing over the conductive channel region and the non-conductive material; and
an isolation wall clamping sidewalls of the convex structure.

6. The transistor structure in claim 5, further comprising a STI layer surrounding the isolation wall.

7. The transistor structure in claim 5, further comprising a spacer layer on a sidewall of the gate region.

8. The transistor structure in claim 7, further comprising:
a first concave being in the convex structure and accommodating the source region, wherein an edge of the first concave is aligned or substantially aligned with an edge of the gate region; and
a second concave being in the convex structure and accommodating the drain region, wherein an edge of the second concave is aligned or substantially aligned with another edge of the gate region;
wherein the source region and the drain region are independent from the substrate.

9. The transistor structure in claim 8, wherein the source region comprises:
an LDD region laterally extending from the first end of the conductive channel region;
a heavily doped region laterally extending from the LDD region; and
a metal region contacting the heavily doped region.

10. The transistor structure in claim 8, further comprising:
an L-shape oxide layer positioned in the first concave, wherein the oxide layer comprises a vertical portion facing the conductive channel region and a lateral portion covering a bottom of the first concave.

11. A transistor structure comprising:
a substrate with a convex structure, wherein the convex structure has a conductive channel region which comprises a first vertical conductive sheet and a second vertical conductive sheet;
wherein the first vertical conductive sheet is separate from the second vertical conductive sheet by a central pole positioned in the conductive channel region.

12. The transistor structure in claim 11, wherein a width of the first vertical conductive sheet or the second vertical conductive sheet is between 1˜5 nm.

13. The transistor structure in claim 11, wherein a height of the non-conductive sheet is between 30˜60 nm.

14. The transistor structure in claim 13, wherein a length of the central pole is shorter than that of the first vertical conductive sheet or the second vertical conductive sheet.

15. The transistor structure in claim 11, further comprising:
a source region contacting with a first end of the conductive channel region, and electrically connecting to the first vertical conductive sheet and the second vertical conductive sheet;
a drain region contacting with a second end of the conductive channel region, and electrically connecting to the first vertical conductive sheet and the second vertical conductive sheet; and
a gate region crossing over the conductive channel region and the central pole;
wherein a bottom of a gate conductive material of the gate region outside the convex structure is lower than the bottom surface of the source region or the drain region.

16. The transistor structure in claim 11, further comprising a selective grown semiconductor layer covering the first vertical conductive sheet and the second vertical conductive sheet.

17. A transistor structure comprising:
a substrate with a convex structure, wherein the convex structure has a conductive channel region;
a first conductive region contacting with a first end of the conductive channel region; and
a second conductive region contacting with a second end of the conductive channel region;
wherein a conductive current during an ON state of the transistor structure is diverged in the conductive channel region extending from the first conductive region to the second conductive region.

18. The transistor structure in claim 17, wherein the conductive current is diverged into multiple paths in the conductive channel region.

19. The transistor structure in claim 17, wherein a leakage current during an OFF state of the transistor structure is lower than 1 pA.

20. A transistor structure comprising:
a substrate with a convex structure, wherein the convex structure comprises a conductive channel region made of a semiconductor material;
a trench formed in the convex structure, wherein the trench is encompassed by a ring shape of the semiconductor material; and
a gate region crossing over the conductive channel region and the trench.

21. The transistor structure in claim 20, wherein the conductive channel region comprises the ring shape of the semiconductor material.
